(19) United States
(12) Patent Application Publication
(10) Pub. No.: US 2019/0184684 A1
(43) Pub. Date: Jun. 20, 2019

(54) Photovoltaic cell

(71) Applicant: Invent S.r.l., Noventa di Piave (IT)

(72) Inventor: Sante Bortoletto, Noventa di Piave (IT)

(21) Appl. No.: 16/322,090

(22) PCT Filed: Aug. 7, 2017
(86) PCT No.: PCT/IB2017/054814

§ 371 Date: Jan. 30, 2019

(30) Foreign Application Priority Data
Aug. 5, 2016 (IT) 102016000083087
Nov. 7, 2016 (IT) 102016000111583

(51) Int. Cl. B32B 17/10; B32B 27/30; B32B 27/36; H01L 31/049; H02S 40/32; H02S 40/38; F21S 9/03

(52) U.S. Cl. CPC B32B 17/10018; B32B 17/10266; B32B 17/10541; B32B 27/306; B32B 27/36; H01L 31/049; B32B 2457/12; H02S 40/38; F21S 9/037; B32B 2307/4023; B32B 2307/4026; B32B 2307/754; B32B 2451/00; H02S 40/32

(57) ABSTRACT

A photovoltaic panel includes an assembly having an array of photovoltaic cells interposed and laminated between two layers of encapsulating material, a glass sheet coupled to a front surface adapted to be exposed of the assembly, and a sheet of an electrically insulating material coupled to the back surface of the assembly, wherein the glass sheet includes at least one decoration obtained by a process carried out directly on the surface of the glass sheet and/or within the thickness of the glass sheet.

### FIELD OF THE INVENTION

The present invention relates to an improved photovoltaic panel.

### BACKGROUND OF THE INVENTION

It is known that a photovoltaic panel is an optoelectronic device comprising an array of photovoltaic cells capable of converting the incident solar energy into electrical energy by photovoltaic effect.

Traditional photovoltaic panels are not completely satisfactory since they are rather expensive and complicated to install, and generally require dedicated external equipment (e.g. inverters) which must be suitably connected to the grid.

Additionally, the aesthetics of traditional photovoltaic panels are poor and, therefore, their diffusion, particularly in the urban domestic context, is rather limited.

US2008/0006323 describes a photovoltaic panel which comprises an array of photovoltaic cells interposed between two layers of encapsulating material. In addition, the upper layer of encapsulating material (the one intended to be exposed) is covered by an upper glass sheet, while the lower layer of encapsulating material is covered by a back sheet. An infrared-transmissive coating film is also made to adhere to the upper/outer surface of the upper glass sheet. In particular, such a coating film has a surface coating with a certain three-dimensional ornamental pattern and/or comprises a pigment which absorbs radiation in the visible spectrum and which is arranged so as to define a particular ornamental pattern. In the various embodiments of US2008/0006323, the infrared-transmissive coating film is placed below the upper glass sheet and is therefore covered by the latter, or is defined within the upper layer of encapsulating material. In essence, in all the embodiments provided in US2008/0006323, the decoration, both in terms of color and in terms of three-dimensional pattern, is obtained by adding a further film (i.e., the coating film) above or below the upper glass sheet, or is defined within the encapsulating material. This type of solution is not completely satisfactory because it is particularly complicated to be implemented, and therefore more expensive to be implemented since, once said coating film has been arranged, it must be suitably coupled with the remaining panel layers and sheets.

US2012/0247541 describes a colored photovoltaic panel consisting of an array of photovoltaic cells interposed between two layers of encapsulating material. In addition, the upper layer of encapsulating material (the one intended to be exposed) is covered by a transparent enamel layer, made of glass or polymeric material, and provided with an upper anti-reflective coating. According to US2012/0247541, the upper coating, the enamel layer and/or the upper layer of encapsulating material are configured so as to modify the overall appearance of the photovoltaic panel as the light incident on the panel itself varies. This solution is particularly elaborate since it requires a plurality of machining operations which must be carefully carried out and combined so that, once installed, the photovoltaic panel can change appearance according to the incident light.

CN204531247 describes an array of photovoltaic cells with around a frame of LEDs which are installed so as to be directed towards the front surface, i.e. that intended to be exposed, of the panel itself. The array of photovoltaic cells is associated at the back with a thermal insulating layer which, in turn, is associated with a wooden layer. From the upper edge of the LED frame protrudes a box structure containing the battery and the control module. This type of solution is not completely satisfactory because it is particularly complicated to be implemented and also simply has a lit frame, without providing for any lighting of the inner area of the panel itself or of the areas around it.

WO2013/143589 describes a lighting device consisting of one or more photovoltaic cells embedded within a layer of encapsulating material, a light-transparent front layer and a back layer. Inside the layer of encapsulating material are also incorporated lighting means which are electrically connected to the photovoltaic cells. This solution is not satisfactory because the insertion of the lighting means inside the layer of encapsulating material makes it constructively rather complicated and, moreover, does not allow the replacement/maintenance of said lighting means to be easily carried out. Moreover, the solution of WO2013/143589 does not relate to a photovoltaic panel, but a type of lighting device of the self-powered type, since the photovoltaic cells are only provided for transforming, by photovoltaic effect, the incident sunlight into electrical energy which is intended for supplying the lighting means; in essence, in the device of WO2013/143589, the electrical energy generated by the photovoltaic cells of the device itself is not in any way intended to supply an external utility which is associated/connected to the device.

ES1073255 describes a tile or shingle which consists of a layer which frontally has a plurality of microholes covered by a protective film, while a single photovoltaic cell is provided at the back. At the edges of said layer is an integrated circuit provided with LEDs which illuminate, through the microholes, the upper surface of said layer. Covering bands are provided at the edges of the tile or shingle in order to prevent the illumination of each tile or shingle from being spread also to the adjacent ones.

WO02052192 describes a lighting element with two glass panels arranged as a sandwich, that is to say, facing each other, and mounted on a lower U-shaped structure, inside of which LEDs are incorporated. In particular, the configuration of this element is such that the light generated by the LEDs is projected and diffused by means of the above two glass panels outwards. Photovoltaic cells are applied to the inner surface of one of the two panels which transform, by photovoltaic effect, the incident sunlight into electrical energy which is intended to supply the LEDs of the device itself.

### SUMMARY OF THE INVENTION

The present invention is intended to provide an improved photovoltaic panel capable of eliminating the drawbacks of traditional panels and of having a remarkable simplicity of installation.

Another object of the invention is to propose a panel which represents the optimal solution, in terms of implementation simplicity, for changing the aesthetic appearance of a traditional photovoltaic panel.

Another object of the invention is to propose a low aesthetic impact panel and/or a panel which can be easily integrated in a home or building context, without in any way defacing the surrounding territory.

Another object of the invention is to propose a panel which is highly customizable and with a pleasant aesthetic aspect and suitable for providing the user with the feeling of being in front of a high quality product, both aesthetically and functionally.

Another object of the invention is to propose a panel for home users which is high performance.

Another object of the invention is to propose a panel which is autonomous and independent from the national grid (i.e. “off-grid”).

Another object of the invention is to propose a panel which can be produced in series and quickly and efficiently.

Another object of the invention is to propose a panel which has an alternative characterization, both in terms of construction and functionality, compared to the traditional ones.

Another object of the invention is to propose a panel which appears visually different from the traditional ones, without changing the efficiency of the panel itself.

Another object of the invention is to propose a panel which is particularly compact and which integrates in its interior a large part or all of the elements necessary for its operation.

Another object of the invention is to propose a panel which is high standard, both functionally and aesthetically, thus allowing the possibility of a spreading thereof on a large scale.

All these objects, taken alone or in any combination thereof, and others which will appear from the following description are achieved, according to the invention, with an improved photovoltaic panel having the features described hereinafter.

### BRIEF DESCRIPTION OF THE DRAWINGS

The present invention is further clarified hereinafter in a preferred embodiment thereof described by way of non-limiting example only with reference to the accompanying drawings, in which:

FIG. 1 shows a front perspective view of a photovoltaic panel according to the invention,

FIG. 2 shows it in a rear perspective view,

FIG. 3 shows it in an exploded view,

FIG. 4 shows a front perspective view of an enlarged detail of a first embodiment of the panel according to the invention,

FIG. 5 shows it in the same view as FIG. 4 in a second embodiment thereof,

FIG. 6 shows a front view of a component of the panel according to the invention,

FIG. 7 shows a front view of a panel according to the invention with the component in FIG. 6,

FIG. 8 shows a front view of a third embodiment of the photovoltaic panel according to the invention,

FIG. 9 shows a perspective view of an enlarged detail of FIG. 8,

FIG. 10 shows a rear view of the panel in FIG. 8,

FIG. 11 shows a front view of a fourth embodiment of the panel according to the invention in a non-lit condition,

FIG. 12 shows a front view of the panel in FIG. 11 in a lit condition,

FIG. 13 shows a front view of a fifth embodiment of the panel according to the invention in a non-lit condition,

FIG. 14 shows a front view of the panel in FIG. 13 in a lit condition,

FIG. 15 shows a top perspective view of a detail of a panel according to the invention,

FIG. 16 shows a side perspective view of a detail of a panel according to the invention, and

FIG. 17 shows a perspective view of an installation comprising multiple panels according to the invention.

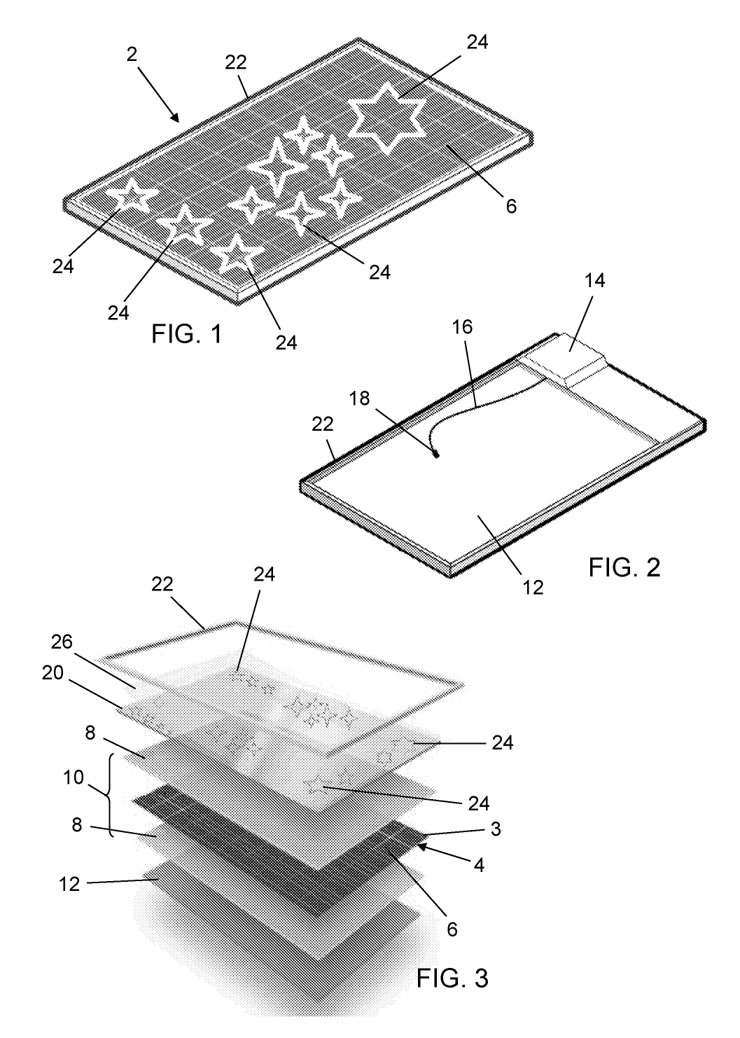

### DETAILED DESCRIPTION OF EMBODIMENTS OF THE INVENTION

As can be seen in the figures, the photovoltaic panel according to the invention comprises an array 3 of photovoltaic cells 4, preferably made of polycrystalline silicon.

Preferably, the panel substantially comprises sixty photovoltaic cells 4 having about 15-18% conversion efficiency.

The photovoltaic cells 4 of array 3 are electrically connected to each other by bars or contour tapes 6 defined as ribbons, which are preferably made of copper coated with a tin alloy.

Array 3 of photovoltaic cells 4 is interposed between two layers of encapsulating material 8, preferably EVA (ethylene-vinyl acetate), so as to form an assembly 10. Suitably, such an assembly 10 is subjected to a thermal vacuum baking process (rolling) so that the two layers of encapsulating material 8 are transformed into a gel which incorporates the photovoltaic cells 4.

Moreover, the back layer of encapsulating material 8 is associated with a back sheet 12 which suitably consists of a material, preferably plastic, which has the function of electrically insulating, protecting and shielding array 3 of photovoltaic cells 4 from external agents (rain and moisture). Preferably, the back sheet 12 consists of a polyester laminate which ensures a high sealing of the photovoltaic panel itself, in particular forming a barrier against oxygen and moisture.

In one embodiment, the back sheet is associated with members adapted to hang the photovoltaic panel in a vertical or inclined position on a wall.

Advantageously, the back sheet 12, which forms the back of the photovoltaic panel 2, is associated with a single box body 14 for containing the control and management means of the panel itself.

Suitably, the box body 14 is closed on all its sides and only an electrical cable 16 protrudes therefrom, provided at the end thereof with an electrical connector 18 for connecting panel 2 to the home and/or national grid.

Advantageously, the control and management system of the photovoltaic panel 2, which is contained in the box body 14, comprises a micro-inverter and/or a transformer (not shown) for providing an alternating current in output from the panel itself, i.e. at the electrical connector 18 of cable 16.

Advantageously, as shown in FIG. 10, the back sheet 12, which forms the back of the photovoltaic panel 2, may be associated with a unit 13 for storing electrical energy, preferably consisting of at least one electrical battery, and a controller for controlling the charge/discharge of the electrical energy of unit 13.

Advantageously, the photovoltaic panel 2 may comprise an inverter and/or a transformer (not shown) for providing a suitable alternating current in output from the panel itself, i.e. at cable 16 protruding from the panel and which is provided with the electrical connector 18 for connecting panel 2 to the domestic and/or national grid.

Advantageously, the energy storage unit 13 and the charge controller, the optional inverter and/or the transformer are all integrated and accommodated inside the photovoltaic panel 2. Preferably, the charge controller is accommodated inside the box body 14.

The front layer of encapsulating material is associated with a glass sheet 20. Suitably, the front glass sheet 20 has the function of protecting and ensuring sturdiness to the whole photovoltaic panel 2, maintaining a high transparency thereof.

Preferably, the front sheet 20 is of tempered prismatic solar glass with a high light transmittance and having a thickness of about 2-4 mm.

Advantageously, the picking surface of the front shall sheet 20 is treated with a nanotechnological process which imparts to the surface itself the property of concentrating dirt or scale, without limiting the yield of panel 2 and aiding the periodic cleaning thereof.

The front glass sheet 20 of the photovoltaic panel 2 has a decoration 24 which may be a wording, an image, a color and/or a color combination, etc. Suitably, decoration 24 is obtained by any of glass processing technique, such as laser engraving, screen printing, sandblasting, etc.

Advantageously, a further glass sheet 26 or even multiple additional sheets may be rested on the front glass sheet 20, of particularly reduced thickness and identical or different color with respect to the underlying glass sheet.

Decoration 24 is obtained by processing said front glass sheet 20 carried out exclusively on the surface of the sheet and/or within the thickness thereof. Preferably, decoration 24 is obtained specifically and only by means processing the front surface (i.e. the external one which is exposed) of said glass sheet.

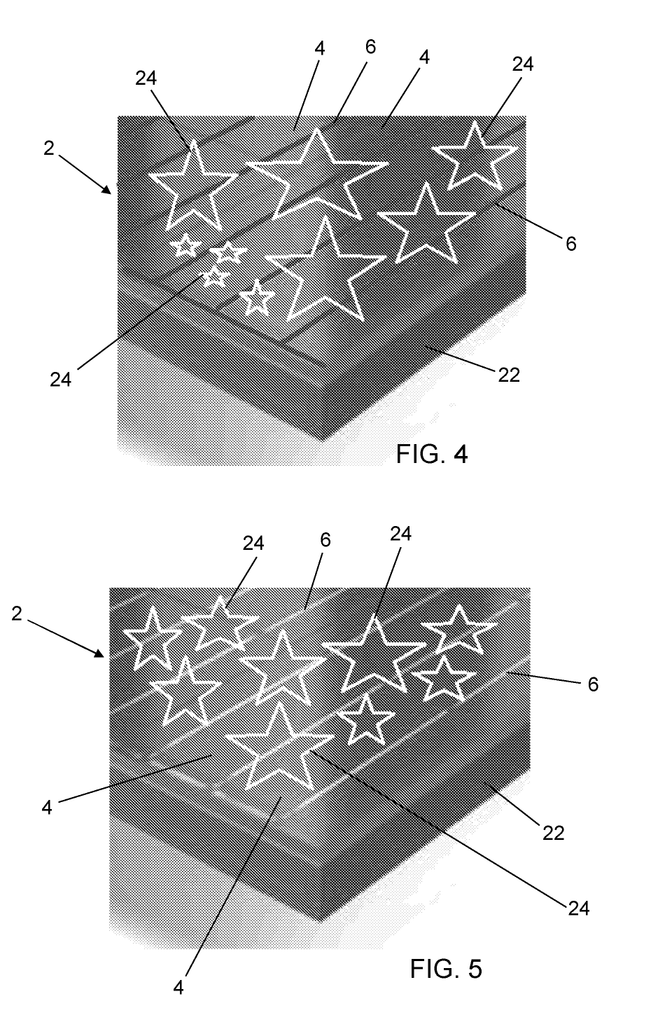

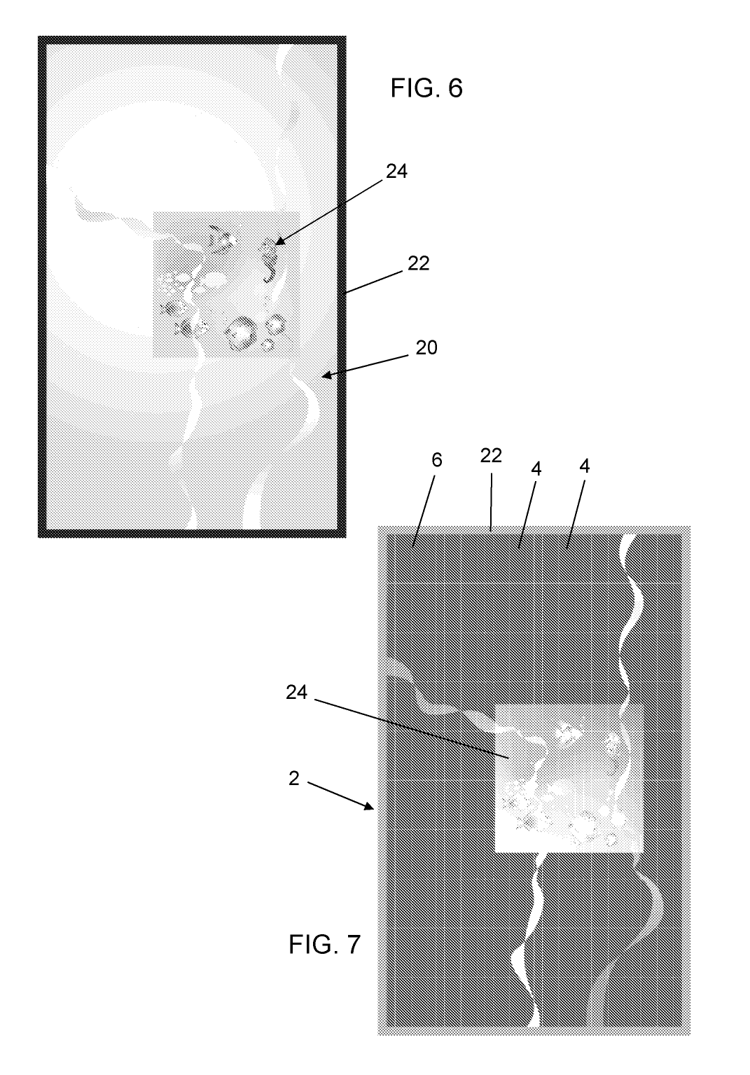

Preferably, as shown in FIG. 4, the bars or contour bands (ribbons) 6 of array 3 of photovoltaic cells 4 are suitably treated, i.e. they are darkened, so as to make them substantially the same color as cells 4; in essence, this allows to have a homogeneous background color for decoration 24 of the front glass sheet 20. Preferably, such treatment is carrying out by applying a suitable paint directly on the bars or contour bands (ribbons) 6 of array 3 of photovoltaic cells 4.

Alternatively, as shown in FIG. 5, the bars or contour bands (ribbons) 6 of array 3 of photovoltaic cells 4, which generally have a different color than that of the cells themselves, are not treated or darkened, and this to make them contribute, together with decoration 24 of the front glass sheet 20, to define the overall decoration of the photovoltaic panel 2. For example, in an embodiment not shown herein, the parallel bars (ribbons) 6 between the photovoltaic cells 4 may define the lines of a musical staff on the background, while in a suitable manner, musical notes are decorated on the front glass sheet 20 so that the overall effect on panel 2 is that typical of a musical score.

Advantageously, decorations 24 of the front glass sheet 20 are positioned and configured so as to cover and/or darken the bars or contour bands (ribbons) 6 of array 3 of photovoltaic cells 4. In particular, to this end, decorations 24 comprise colored stretches/stripes formed on the front glass sheet 20 and of a color substantially corresponding to that of the photovoltaic cells 4. Suitably, the colored stripes are defined on the front sheet 20 in a manner substantially corresponding, from the dimensional, shape and position point of view, to the contour bands (ribbons) 6 of array 3 of photovoltaic cells 4. In essence, by covering the bars or contour bands (ribbons) 6 with decorations 24 of the front glass sheet 20 having the same color as cells 4, the overall effect of a solid and homogeneous base of a single color (i.e. that of the cells) is obtained on panel 2.

In one embodiment, the photovoltaic cells of the array are electrically connected to each other by stretches of a different color than that of the photovoltaic cells.

In one embodiment, the connecting stretches between the photovoltaic cells remain exposed to define, together with the cells, the background for the decoration.

In one embodiment, the connecting stretches between the photovoltaic cells are covered and/or darkened by the decorations of the front glass sheet.

Suitably, in addition to decorations 24 for covering the bars or contour bands (ribbons) 6, further decorations 24 of various shapes and colors may be provided in order to obtain overall a particular ornamental effect on panel 2.

Advantageously, the photovoltaic panel 2 comprises an outer frame 22. Suitably, such a frame 22 may be defined by the edge of the front sheet glass 20, or it may be defined by a profile leans on or is associated with said sheet 20 and which, advantageously, can be configured for holding together the various layers and/or sheets forming the panel itself. Preferably, frame 22 is made of metal or alloys thereof (such as aluminum) and also has the function of ensuring sturdiness and defining a practical attachment for the photovoltaic panel 2.

Advantageously, frame 22 has surface decorations, preferably obtained by engraving. Preferably, frame 22 has chamfered edges.

Advantageously, frame 22 or the back sheet 12 are constrained to supports for attaching the photovoltaic panel 2 in a vertical or also inclined position on a wall, such as of a building.

Advantageously, according to the invention, panel 2 only consists of assembly 10, the front glass sheet 20 and the back sheet of an electrically insulating material 12, i.e. without providing for additional layers, films or coatings.

Advantageously, the footprint of panel 2 is defined by the dimensions of array 3 of photovoltaic cells 4. Preferably, panel 3, and in particular the front glass sheet 20, has length and width corresponding to those of array 3 of photovoltaic cells 4.

Panel 2 according to the invention may comprise lighting means 40 associated with at least one edge of said panel 2 for illuminating the glass sheet 20 and/or the areas around the perimeter of the panel itself. Suitably, the lighting means 40 are associated with the edges of panel 2, i.e. the edges of assembly 10 and/or the glass sheet 20 and/or the back sheet 12 of an electrically insulating material 12, and therefore are not incorporated within the layers 8 of encapsulating material 8.

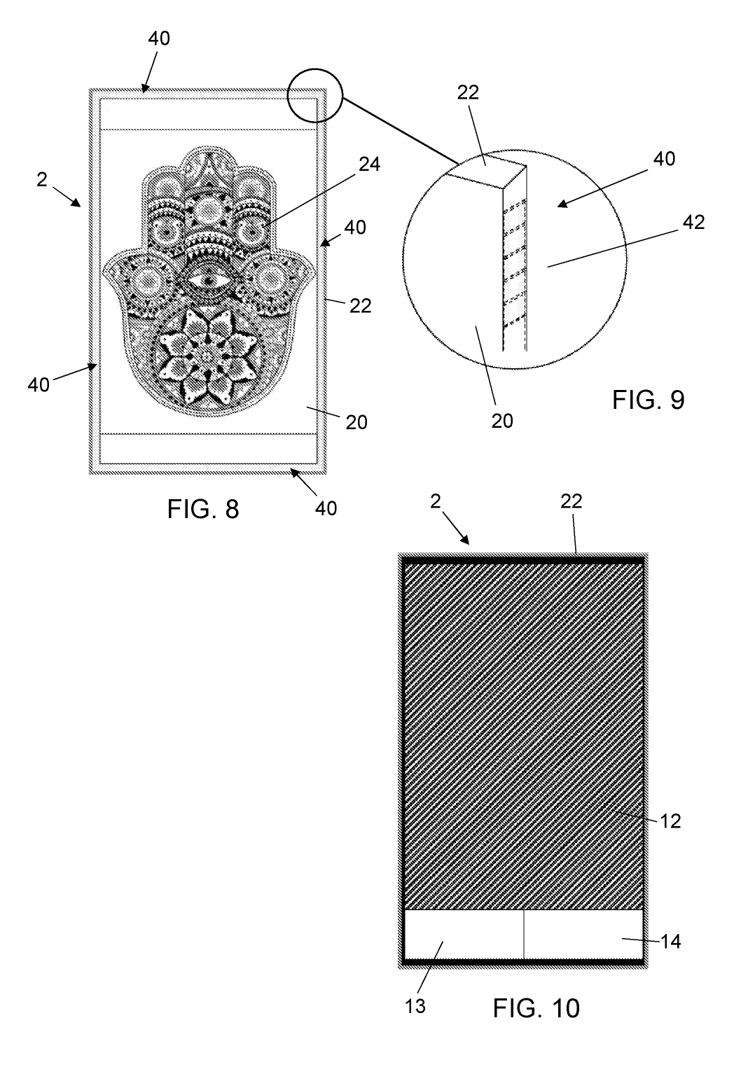

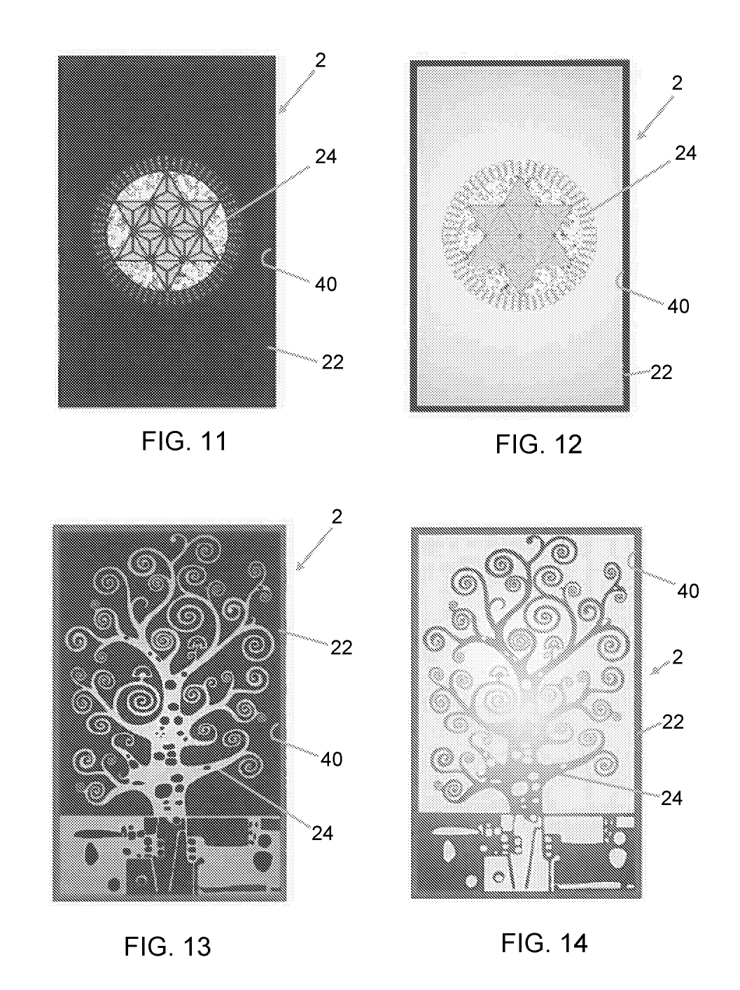

Preferably, a part or the whole frame 22 are associated with lighting means 40, preferably LEDs (see FIGS. 8 and 9). In particular, the LED strips 42 may be associated with frame 22 along a single side, along two sides, preferably opposite to each other, or along all the four sides thereof, either by the entire length of the sides or by a part only thereof.

Suitably, the lighting means 40 are associated with frame 22 so as to illuminate decoration 24 of the glass sheet 20. In particular to this end, the lighting means 40 are arranged and oriented so as to illuminate the front (i.e. exposed) and internal portion of the panel itself (see FIGS. 12 and 14).

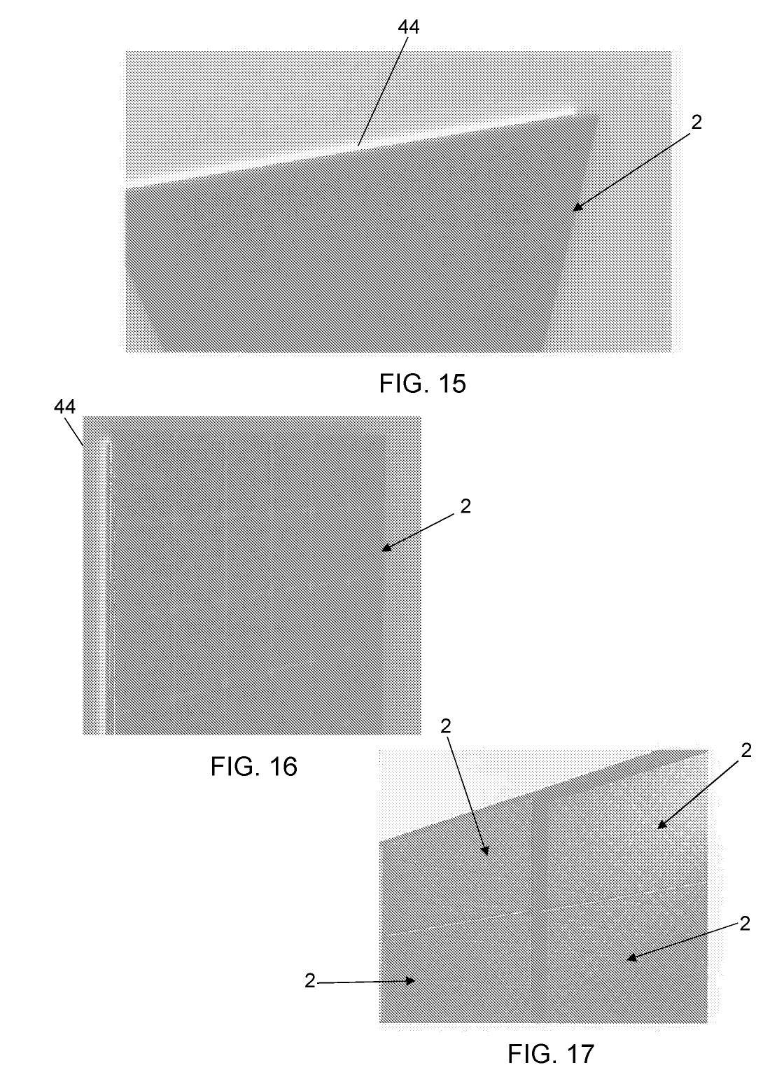

Suitably, the lighting means 40 are associated with frame 22 so as to illuminate the back side of the panel and/or the external areas around the frame itself (see FIGS. 15 and 16). Preferably, the lighting means 40 are configured and arranged to create a diffused light 44, which expands outwards at the back side of the panel.

Advantageously, the lighting means 40 are electrically connected to the storage unit 13 so as to be supplied by the electrical energy stored in the latter.

Advantageously, the lighting means 40 are electrically connected directly with array 3 of photovoltaic cells 4 so as to be supplied directly by the electrical energy generated thereby.

The operation of the photovoltaic panel 2 according to the invention clearly appears from the foregoing description. In particular, array 3 of photovoltaic cells 4 converts, by photovoltaic effect, the incident sunlight into direct current which then, through the charge controller 14, is stored in the storage unit 13 or is sent directly to the inverter which converts it into alternating current for the immediate consumption by a utility external to the panel itself.

Advantageously, the electrical energy generated in the panel itself and stored in the storage unit 13 is used for supplying the lighting means 40 associated and integrated into the panel itself. Advantageously, the electrical energy generated in the panel itself is used, without being stored in the storage unit 13, for directly supplying the lighting means 40 associated and integrated into the panel itself.

It is also understood that, in an alternative embodiment of panel 2 according to the invention, the latter may be lacking the connecting means to a utility and that the electrical energy generated by array 3 of photovoltaic cells 4, possibly stored in the storage unit 13, may be used only for operating the lighting means 40 provided within the panel itself. In particular, in such circumstances, panel 2 only has an ornamental function and/or a function of illuminating the installation room or area, i.e. without any function of supplying energy to the utilities.

The panel according to the invention may be installed and used individually, especially if it is intended for a domestic context, but it may also be suitably connected and combined with other panels according to the invention (see FIG. 17). In the latter case, the single photovoltaic panels 2 according to the invention may be conveniently combined so that the combination of decorations 24 and/or lighting means 40 of each panel 2 defines a unique overall aesthetic effect.

An installation according to the invention may provide a single overall aesthetic effect defined by the combination and/or union of the lighting elements and/or of the decorations of each panels.

In an installation according to the invention, the photovoltaic panels may be connected, individually or in a combination, to the home and/or national grid to bring into the grid the electrical energy generated by photovoltaic effect.

Suitably, in this case, the photovoltaic panels 2 are electrically connected to each other and each of them is provided with its own storage unit 13 of electrical energy.

From the foregoing description, it is clear that the improved panel according to the invention is particularly advantageous over the traditional ones, since:

it allows high aesthetic performance as it can be suitably decorated and/or illuminated;

it has a highly attractive appearance even in the absence of natural light,

it has a fine appearance, which enables it to be classified as a quality or luxury product,

it can be produced industrially while the decoration of the glass sheet can be highly customized and be done by hand,

it allows the creation of an autonomous system (“off-grid”) for the supply of electricity; this is especially useful for the supply of electricity to isolated utilities or in situations where it is difficult or impossible to connect to the grid,

it can be easily and quickly connected through its output socket to the domestic grid,

it has excellent features of ease of use and installation since it can be positioned either vertically or inclined,

it is independent and compact since all its components are suitably integrated within the footprint thereof,

it requires a reduced installation space and does not require any external devices, and

it is flexible, modular and scalable according to the needs.

In particular, unlike US2008/0006323 and US2012/0247541, in the panel according to the present invention the decoration is specifically and only made through a process carried out on the surface or inside of the thickness of the glass sheet, without affecting in any way the layer of encapsulating material or providing the presence of further films to be applied to the glass sheet. More specifically, the panel according to the present invention is the optimal solution in terms of ease/simplicity of implementation, for changing/improving the appearance of a conventional photovoltaic panel. In particular, the present solution is different from that of US2012/0247541 in that the latter does not in any way provide the possibility of decorating the panel by only and specifically carrying out a process on the surface of the glass sheet.

Moreover, unlike CN204531247, the lighting means of the present invention do not define a simple illuminated frame as they are specifically configured for illuminating the glass sheet 20 and/or the areas around the perimeter of the panel itself.

Unlike WO2013/143589, the lighting means are associated with at least one edge of the panel itself and, therefore, are not incorporated within the encapsulating material.

Unlike ES1073255 and WO02052192, the present invention specifically relates to a photovoltaic panel comprising an array (i.e. a plurality) of photovoltaic cells interposed and laminated between two layers of encapsulating material and frontally covered by a glass sheet and at the back by a sheet of an electrically insulating material.

The invention claimed is:

1.-39. (canceled)

40. A photovoltaic panel comprising:
an assembly comprising an array of photovoltaic cells interposed and laminated between two layers of an encapsulating material, the photovoltaic cells of the array being electrically connected to each other by connecting stretches of a different color than a color of the photovoltaic cells;
a glass sheet coupled to a front surface, adapted to be exposed, of the assembly; and
a sheet of an electrically insulating plastic material coupled to a back surface of the assembly,
wherein the glass sheet comprises at least one decoration, which is obtained by at least one process carried out directly on one or both of a surface of the glass sheet or within a thickness of the glass sheet, and
wherein the connecting stretches between the photovoltaic cells are covered or darkened by the at least one decoration so as to obtain an overall effect of a solid and homogeneous base of a single color corresponding to a color of the photovoltaic cells.

41. The photovoltaic panel according to claim 40, wherein the at least one decoration comprises one or more of a wording, an image, a color, or a color combination.

42. The photovoltaic panel according to claim 40, wherein a picking surface of the glass sheet is treated with a nano-technological process to impart to the surface of the glass sheet a property of concentrating dirt or scale, without limiting a yield of the photovoltaic panel and facilitating periodic cleaning of the photovoltaic panel.

43. The photovoltaic panel according to claim 40, further comprising a frame, which is applied at an edge of the glass sheet, of the assembly, or of a back sheet of an electrically insulating material.

44. The photovoltaic panel according to claim 43, wherein the frame is configured to hold together layers that make up the photovoltaic panel.

45. The photovoltaic panel according to claim 40, further comprising a box-shaped body, which is associated with a back sheet of an electrically insulating material and which contains a control and management system of the photovoltaic panel.

46. The photovoltaic panel according to claim 45, wherein the control and management system is configured to provide, in output from the photovoltaic panel, an alternating current to be supplied to an external utility.

47. The photovoltaic panel according to claim 45, further comprising an electrical cable connected to the control and management system and provided at an end with an electrical connector that connects the photovoltaic panel to a home or an electric grid.

48. The photovoltaic panel according to claim 40, further comprising, integrated and accommodated in an interior thereof, a unit that stores electrical energy generated by the array of the photovoltaic cells.

49. The photovoltaic panel according to claim 48, further comprising, integrated and accommodated in an interior thereof, a controller that control a charge/discharge of the unit that stores the electrical energy generated by the array of the photovoltaic cells.

50. The photovoltaic panel according to claim 48, wherein the controller and the unit that controls the charge/discharge is accommodated into a box body, a box-shaped body, which is associated with a back sheet of an electrically insulating material.

51. The photovoltaic panel according to claim 40, further comprising one or more lighting elements associated with at least one edge of the photovoltaic panel and adapted to illuminate one or both of the glass sheet or areas around a perimeter of the photovoltaic panel.

52. The photovoltaic panel according to claim 51, wherein the one or more lighting elements associated with a frame, which is applied at an edge of the glass sheet or of a back sheet of an electrically insulating material, and are adapted to illuminate one or both of the glass sheet or outer areas adjacent to the frame of the photovoltaic panel.

53. The photovoltaic panel according to claim 52, wherein the one or more lighting elements comprise an LED strip, which is associated with at least one side of the frame and affect at least a part of a length of a side of the photovoltaic panel.

54. The photovoltaic panel according to claim 51, wherein the one or more lighting elements are arranged and oriented so as to illuminate the decoration of the glass sheet.

55. The photovoltaic panel according to claim 51, wherein the one or more lighting elements are configured and arranged so as to generate, at a back face of the photovoltaic panel or around edges of the photovoltaic panel, an outwardly-extending light.

56. The photovoltaic panel according to claim 51, wherein the one or more lighting elements are powered by electrical energy stored in a unit that stores electrical energy.

57. The photovoltaic panel according to claim 51, wherein the one or more lighting elements are powered directly by electrical energy generated by the array of the photovoltaic cells.

58. An installation comprising:
at least two photovoltaic panels arranged in one or both of a vertical or horizontally flanked configuration,
wherein each of the photovoltaic panels comprises:
an assembly comprising an array of photovoltaic cells interposed and laminated between two layers of an encapsulating material, the photovoltaic cells of the array being electrically connected to each other by connecting stretches of a different color than a color of the photovoltaic cells;
a glass sheet coupled to a front surface, adapted to be exposed, of the assembly; and
a sheet of an electrically insulating plastic material coupled to a back surface of the assembly,
wherein the glass sheet comprises at least one decoration, which is obtained by at least one process carried out directly on one or both of a surface of the glass sheet or within a thickness of the glass sheet, and
wherein the connecting stretches between the photovoltaic cells are covered or darkened by the at least one decoration so as to obtain an overall effect of a solid and homogeneous base of a single color corresponding to a color of the photovoltaic cells.

59. The installation according to claim 58, wherein the installation comprises a single overall decoration defined by a combination or union of the decorations of each of the photovoltaic panels.
